(19) United States
(12) Patent Application Publication
(10) Pub. No.: US 2026/0371956 A1
(43) Pub. Date: Nov. 19, 2026

(54) ALUMINUM BROMIDE PRECURSORS FOR MICROELECTRONIC APPLICATIONS

(71) Applicant: ENTEGRIS, INC., Billerica, MA (US)

(72) Inventors: Drew Michael Hood, Newtown, CT (US); Rong Zhao, Newtown, CT (US); Bryan C. Hendrix, Danbury, CT (US)

(21) Appl. No.: 19/678,337

(22) Filed: May 15, 2026

Related U.S. Application Data
(60) Provisional application No. 63/807,444, filed on May 16, 2025.

(51) Int. Cl. H10P 14/60; C01F 7/02; C23C 16/40; C23C 16/455; H10P 14/692

(52) U.S. Cl. CPC H10P 14/668; C01F 7/02; C23C 16/403; C23C 16/45553; H10P 14/69391

(57) ABSTRACT

Aluminum bromide precursors for deposition processes are provided herein. The aluminum bromide precursor is provided in an assembly comprising a vessel, with the aluminum bromide precursor located within an interior volume of the vessel. The vessel is configured to store and supply the aluminum bromide precursor to a film deposition process. When exposed to a substrate under deposition conditions, the aluminum bromide precursor and an oxidizer form an aluminum oxide film. Related systems, components, apparatuses, devices, and methods, among other things, are also provided herein.

### CROSS-REFERENCE TO RELATED APPLICATIONS

This application claims the benefit under 35 USC 119 of U.S. Provisional Patent Application No. 63/807,444, filed May 16, 2025, the disclosure of which is hereby incorporated herein by reference in its entirety.

### FIELD

The present disclosure relates to aluminum bromide precursors for microelectronic applications.

### BACKGROUND

Various precursors are useful in the fabrication of microelectronic devices, including the fabrication of semiconductor devices. The precursors are vaporized and deposited as films.

### SUMMARY

Some embodiments relate to an assembly. In some embodiments, the assembly comprises a vessel. In some embodiments, the assembly comprises an aluminum bromide precursor located within an interior volume of the vessel. In some embodiments, the vessel is configured to store and supply the aluminum bromide precursor to a film deposition process. In some embodiments, when exposed to a substrate under deposition conditions, the aluminum bromide precursor and an oxidizer form an aluminum oxide film.

Some embodiments relate to a method. In some embodiments, the method comprises obtaining an oxidizer. In some embodiments, the method comprises obtaining an aluminum bromide precursor. In some embodiments, the method comprises exposing, under deposition conditions, at least a substrate to at least an oxidizer. In some embodiments, the method comprises exposing, under deposition conditions, at least the substrate to at least an aluminum bromide precursor to form an aluminum oxide film on the substrate.

Some embodiments relate to a component. In some embodiments, the component comprises a substrate. In some embodiments, the component comprises an aluminum oxide film located on the substrate. In some embodiments, when analyzed by Secondary Ion Mass Spectrometry (SIMS), the aluminum oxide film comprises less than 2% of halide atoms based on a total number of atoms in a cubic centimeter sample of the aluminum oxide film. In some embodiments, the aluminum oxide film comprises less than 2% of bromide atoms and substantially free of chloride atoms based on a total number of atoms in a cubic centimeter sample of the aluminum oxide film as analyzed by SIMS. In some embodiments, the aluminum oxide film comprises less than 1%, 0.5%, 0.25%, 0.1%, or 0.01% of bromide atoms and substantially free of chloride atoms based on a total number of atoms in a cubic centimeter sample of the aluminum oxide film as analyzed by SIMS. In some embodiments, substantially free of chloride atoms corresponds to less than 0.1% of chloride atoms when the aluminum oxide film is assessed by SIMS. In some embodiments, substantially free of chloride atoms corresponds to less than 0.01% of chloride atoms when the aluminum oxide film is assessed by SIMS. In some embodiments, substantially free of chloride atoms corresponds to less than 0.001% of chloride atoms when the aluminum oxide film is assessed by SIMS. In some embodiments, the amount of chloride atoms is below a detection limit for the SIMS.

### DRAWINGS

FIG. 1 is a schematic diagram of a vessel for storing and delivering a precursor, according to some embodiments.

FIG. 2 is a flowchart of a method for forming a film, according to some embodiments.

FIG. 3 is a schematic diagram of a cross-section of a component, according to some embodiments.

FIG. 4 is a graphical view illustrating thickness of a film at different locations on the substrate, according to some embodiments.

FIG. 5 is a graphical view illustrating thickness of a film for various ozone pulse times, according to some embodiments.

FIG. 6 is a graphical view illustrating thickness of a film on a substrate, according to some embodiments.

FIG. 7 is a graphical view illustrating aluminum oxide thickness for various aluminum bromide precursor pulse times, according to some embodiments.

FIG. 8 is a graphical view illustrating aluminum oxide thickness for various temperatures, according to some embodiments.

FIG. 9 is a graphical view illustrating aluminum oxide thickness for various cycles, according to some embodiments.

FIG. 10 is a graphical view illustrating thickness of a film on a substrate, according to some embodiments.

FIG. 11 is a graphical view illustrating aluminum oxide thickness for different precursors for various oxidizer pulse times, according to some embodiments.

FIG. 12 is a Scanning Electron Microscopy (SEM) image of step coverage for an aluminum oxide film, according to some embodiments.

FIG. 13 is a SEM image of step coverage for an aluminum oxide film, according to some embodiments.

FIG. 14 is a SEM image of step coverage for an aluminum oxide film, according to some embodiments.

### DETAILED DESCRIPTION

Some embodiments relate to precursors and related methods. At least some of these embodiments relate to precursors useful in the fabrication of microelectronic devices, including semiconductor devices, and the like. For example, the precursors can be used to form aluminum-containing films such as aluminum oxide by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

Some embodiments relate to a precursor for deposition processes in the fabrication of microelectronic devices, including, for example and without limitation, semiconductor devices, among others. The precursor can comprise an aluminum bromide precursor. For example, in some embodiments, the precursor comprises AIBr₃. Although it would have been expected for an aluminum bromide precursor to be less volatile than aluminum chloride (AlCl₃), the aluminum bromide precursors disclosed herein are unexpectedly more volatile than AlCl₃. Consistent with this difference in volatility, it was discovered that AlBr₃ had a lower melting point than AlCl₃. Moreover, the aluminum bromide precursors disclosed herein can exist in a liquid phase at delivery temperatures and films formed from the aluminum bromide precursors disclosed herein exhibit numerous unexpected advantages over other precursors, including other aluminum halide precursors.

The aluminum bromide precursor can be deposited at a deposition rate of at least 1.1 Ångstroms per cycle. For example, in some embodiments, when exposed under deposition conditions to a substrate, the aluminum bromide precursor and an oxidizer form a film on a substrate at a deposition rate of 1.1 Angstroms per cycle to 3 Ångstroms per cycle, or any range or subrange between 1.1 Ångstroms per cycle and 3 Ångstroms per cycle. In some embodiments, the aluminum bromide precursor and an oxidizer form a film on a substrate at a deposition rate of 1.1 Angstroms per cycle to 2 Ångstroms per cycle, 1.1 Ångstroms per cycle to 1.9 Ångstroms per cycle, 1.1 Ångstroms per cycle to 1.8 Ångstroms per cycle, 1.1 Ångstroms per cycle to 1.7 Ångstroms per cycle, 1.1 Ångstroms per cycle to 1.6 Ångstroms per cycle, 1.1 Ångstroms per cycle to 1.5 Ångstroms per cycle, 1.1 Ångstroms per cycle to 1.4 Ångstroms per cycle, 1.1 Ångstroms per cycle to 1.3 Ångstroms per cycle, 1.1 Ångstroms per cycle to 1.2 Ångstroms per cycle, 1.2 Ångstroms per cycle to 1.9 Ångstroms per cycle, 1.3 Ångstroms per cycle to 1.9 Ångstroms per cycle, 1.4 Ångstroms per cycle to 1.9 Ångstroms per cycle, 1.5 Ångstroms per cycle to 1.9 Ångstroms per cycle, 1.6 Ångstroms per cycle to 1.9 Ångstroms per cycle, 1.7 Ångstroms per cycle to 1.9 Ångstroms per cycle, or 1.8 Ångstroms per cycle to 1.9 Ångstroms per cycle.

As used herein, the term “step coverage” refers to a ratio of a thickness of a film on a first surface to a thickness of the film on a second surface (e.g., of the same substrate). In some embodiments, the first surface of the substrate and the second surface of the substrate are different. For example, in some embodiments, the first surface of the substrate is a surface at the bottom of a high aspect ratio structure (e.g., a trench) and the second surface of the substrate is a surface at the top of the high aspect ratio structure (e.g., a trench). As disclosed herein, non-limiting examples of high aspect ratio structures include, for example and without limitation, at least one of a trench, a plenum, a cavity, a hole, a channel, or any combination thereof. It will be appreciated that other structures would have high aspect ratios and thus these shall not be limiting.

The aluminum bromide precursor can be deposited to form a film having a step coverage of at least 90%. For example, in some embodiments, the aluminum bromide precursor is deposited to form a film, on a feature having an aspect ratio of at least 2:1, of at least 90%.

In some embodiments, the aluminum bromide precursor is deposited to form a film, on a feature having an aspect ratio of at least 2:1, of at least 90%. In some embodiments, the aluminum bromide precursor is deposited to form a film, on a feature having an aspect ratio of at least 2:1, of 90% to 99%, 90% to 98%, 90% to 97%, 90% to 96%, 90% to 95%, 90% to 94%, 90% to 93%, 90% to 92%, 90% to 91%, 91% to 99%, 92% to 99%, 93% to 99%, 94% to 99%, 95% to 99%, 96% to 99%, 97% to 99%, or 98% to 99%. In some embodiments, the aluminum bromide precursor is deposited to form a film, on a feature having an aspect ratio of at least 2:1, of 100%. The feature can have an aspect ratio of 2:1 to 100:1, 2:1 to 90:1, 2:1 to 80:1, 2:1 to 70:1, 2:1 to 60:1, 2:1 to 50:1, 2:1 to 40:1, 2:1 to 30:1, 2:1 to 20:1, 2:1 to 10:1, 2:1 to 9:1, 2:1 to 8:1, 2:1 to 7:1, 2:1 to 6:1, 2:1 to 5:1, 2:1 to 4:1, 2:1 to 3:1, 5:1 to 100:1, 10:1 to 100:1, 20:1 to 100:1, 30:1 to 100:1, 40:1 to 100:1, 50:1 to 100:1, 60:1 to 100:1, 70:1 to 100:1, 80:1 to 100:1, or 90:1 to 100:1. In some embodiments, the feature has an aspect ratio of greater than 100:1, such as, for example and without limitation, 1000:1, or any subrange between 100:1 and 1000:1.

The aspect ratio of the structure can refer to a ratio of two of a width, a depth, a height, a length, or a diameter, in any combination. In some embodiments, for example, the aspect ratio refers to the ratio of a depth of a circular hole (e.g., a pore, etc.) to a diameter of the circular hole (e.g., the pore, etc.). In some embodiments, the aspect ratio refers to the ratio of a depth of a non-circular hole (e.g., a trench, etc.) to a width of the non-circular hole (e.g., the trench, etc.). Non-limiting examples of substrates, including high-aspect ratio substrates, include, without limitation, at least one of a membrane, a showerhead, a liner, a tube, a gas line, a valve, an injector, a tray, or any combination thereof.

In some embodiments, such as blanket wafers or other relatively flat substrates, the aluminum bromide precursor can achieve saturation at an oxidizer pulse duration of no greater than 10 seconds. For example, in some embodiments, the aluminum bromide precursor can achieve saturation at an oxidizer pulse duration of no greater than 9 seconds, no greater than 8 seconds, no greater than 7 seconds, no greater than 6 seconds, no greater than 5 seconds, no greater than 4 seconds, no greater than 3 seconds, no greater than 2 seconds, or no greater than 1 second. In complex geometries, such as NAND structures, the saturation time may be longer, for example up to 1 minute, 5 minutes, or 10 minutes.

The aluminum bromide precursor can be deposited to form a film having a uniform thickness. For example, in some embodiments, when exposed to a substrate under deposition conditions, the aluminum bromide precursor and an oxidizer form the aluminum oxide film having a thickness that is within 10% of an average thickness of the aluminum oxide film. For example, in some embodiments, the aluminum bromide precursor and an oxidizer form the aluminum oxide film having a thickness that is within 9%, 8%, 7%, 6%, 5%, 4%, 3%, 2%, 1%, or 0.1% of an average thickness of the aluminum oxide film.

The aluminum bromide precursor can be deposited to form high purity films. For example, in some embodiments, when analyzed by Secondary Ion Mass Spectrometry (SIMS), the aluminum oxide film comprises less than 2% of halide atoms based on a total number of atoms in a cubic centimeter sample of the aluminum oxide film. For example, in some embodiments, the aluminum oxide film comprises 0.001% to 2% of halide atoms based on a total number of atoms in a cubic centimeter sample of the aluminum oxide film, or any range or subrange between 0.001% and 2%. In some embodiments, the aluminum oxide film comprises 0.001% to 2%, 0.001% to 1.9%, 0.001% to 1.8%, 0.001% to 1.7%, 0.001% to 1.6%, 0.001% to 1.5%, 0.001% to 1.4%, 0.001% to 1.3%, 0.001% to 1.2%, 0.001% to 1.1%, 0.001% to 1%, 0.001% to 0.9%, 0.001% to 0.8%, 0.001% to 0.7%, 0.001% to 0.6%, 0.001% to 0.5%, 0.001% to 0.4%, 0.001% to 0.3%, 0.001% to 0.2%, 0.001% to 0.1%, 0.001% to 0.01%, 0.01% to 2%, 0.1% to 2%, 0.2% to 2%, 0.3% to 2%, 0.4% to 2%, 0.5% to 2%, 0.6% to 2%, 0.7% to 2%, 0.8% to 2%, 0.9% to 2%, 1% to 2%, 1.1% to 2%, 1.2% to 2%, 1.3% to 2%, 1.4% to 2%, 1.5% to 2%, 1.6% to 2%, 1.7% to 2%, 1.8% to 2%, or 1.9% to 2% of halide atoms based on a total number of atoms in a cubic centimeter sample of the aluminum oxide film. In some embodiments, the halide atoms are bromide atoms and the film is substantially free of chloride atoms.

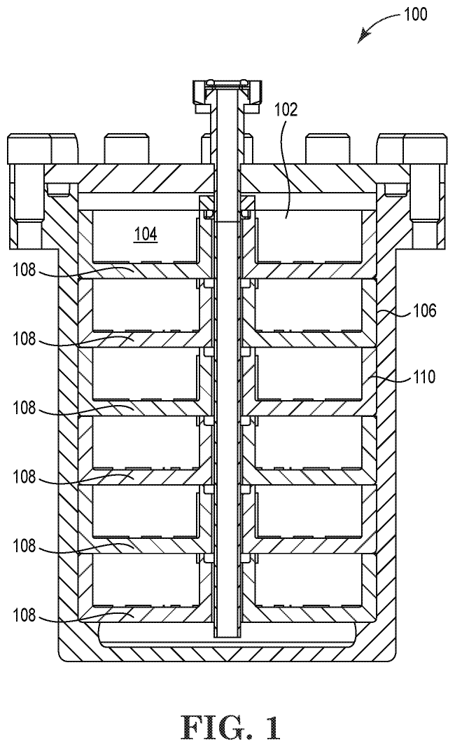

FIG. 1 is a schematic diagram of a cross-section of an assembly, according to some embodiments. As shown in FIG. 1, in some embodiments, the assembly comprises a vessel (or ampoule) 100 for storing and supplying an aluminum bromide precursor to a deposition process. When, for example, the aluminum bromide precursor is present in a solid phase, the vessel 100 can comprise a tray assembly 102 in an interior volume 104 of the vessel 100. The tray assembly 102 can comprise trays 108, each of which can be configured to contain the aluminum bromide precursor. The trays 108 can be wholly or partially constructed of at least one of a graphite material, an aluminum material, an alloy material, or any combination thereof. A portion 110 of each tray 108 can be configured to be in contact (e.g., thermal contact, direct contact, etc.) with at least a portion of an inner surface 106 of the vessel 100 to facilitate heat transfer to the aluminum bromide precursor. Alternatively, when the aluminum bromide precursor is present in a phase other than a solid phase, such as, a liquid phase or a gas/vapor phase, the tray assembly 102 can be omitted from the vessel.

The vessel 100 can be configured to store the aluminum bromide precursor under various conditions to control, among other things, the phase in which the aluminum bromide precursor is present in the vessel 100. For example, in some embodiments, the aluminum bromide precursor is contained in the interior volume 104 of the vessel 100 under conditions where the aluminum bromide precursor is present as a liquid. In some embodiments, the aluminum bromide precursor is contained in the interior volume 104 of the vessel 100 under conditions where the aluminum bromide precursor is present as a solid. In some embodiments, when the aluminum bromide precursor is present in the vessel 100 at delivery conditions (e.g., delivery temperature and/or delivery pressure), the aluminum bromide precursor is present in a liquid phase. When the aluminum bromide precursor is vaporized, the vessel 100 can be configured to direct the aluminum bromide precursor through any of a number of different flow paths, either upwards, downwards, or both.

The delivery conditions can include a delivery temperature. In some embodiments, the delivery temperature is a temperature in a range of 50 °C to 200 °C, or any range or subrange between 50 °C and 200 °C. For example, in some embodiments, the delivery temperature is a temperature in a range of 50 °C to 200 °C, 50 °C to 190 °C, 50 °C to 180 °C, 50 °C to 170 °C, 50 °C to 160 °C, 50 °C to 150 °C, 50 °C to 140 °C, 50 °C to 130 °C, 50 °C to 120 °C, 50 °C to 110 °C, 50 °C to 100 °C, 50 °C to 90 °C, 50 °C to 80 °C, 50 °C to 70 °C, 50 °C to 60 °C, 60 °C to 200 °C, 70 °C to 200 °C, 80 °C to 200 °C, 90 °C to 200 °C, 100 °C to 200 °C, 110 °C to 200 °C, 120 °C to 200 °C, 130 °C to 200 °C, 140 °C to 200 °C, 150 °C to 200 °C, 160 °C to 200 °C, 170 °C to 200 °C, 180 °C to 200 °C, or 190 °C to 200 °C.

The delivery conditions can comprise a delivery pressure. In some embodiments, the delivery pressure is a pressure in a range of 0.01 Torr to 100 Torr, or any range or subrange between 0.01 Torr and 100 Torr. For example, in some embodiments, the delivery pressure is a pressure in a range of 0.01 Torr to 100 Torr, 0.01 Torr to 90 Torr, 0.01 Torr to 80 Torr, 0.01 Torr to 70 Torr, 0.01 Torr to 60 Torr, 0.01 Torr to 50 Torr, 0.01 Torr to 40 Torr, 0.01 Torr to 30 Torr, 0.01 Torr to 20 Torr, 0.01 Torr to 10 Torr, 0.01 Torr to 0.1 Torr, 0.1 Torr to 100 Torr, 1 Torr to 100 Torr, 10 Torr to 100 Torr, 20 Torr to 100 Torr, 30 Torr to 100 Torr, 40 Torr to 100 Torr, 50 Torr to 100 Torr, 60 Torr to 100 Torr, 70 Torr to 100 Torr, 80 Torr to 100 Torr, or 90 Torr to 100 Torr.

In some embodiments, the precursor is supplemented with a carrier gas, such as argon or nitrogen (N₂). The carrier gas may be bubbled through the liquid precursor.

In some embodiments, when exposed under deposition conditions to a substrate, the aluminum bromide precursor and an oxidizer are configured to form an aluminum oxide film on the substrate. In some embodiments, when exposed under deposition conditions to a substrate, the aluminum bromide precursor and an oxidizer are configured to react to form an aluminum oxide film on the substrate. In some embodiments, the aluminum bromide precursor is AIBr₃.

In some embodiments, the deposition process includes one or more optional purge steps. Purge steps may be performed after any or all of the material delivery steps. Purge may be performed by flowing a purge gas into the deposition chamber. The purge gas may be any suitable, non-reacting gas (or mixture of such gases). Examples of suitable purge gases include noble gases, such as helium and argon, and nitrogen (N₂).

The deposition conditions may use any temperatures, pressures, pulse times, purge times, cycles, cycle counts, etc. disclosed in this document including in the Examples, below.

In some embodiments, when exposed under deposition conditions to a substrate, the aluminum bromide precursor and an oxidizer form a film on a substrate at a deposition rate of at least 1.1 Angstroms per cycle. For example, in some embodiments, the aluminum bromide precursor and an oxidizer form a film on a substrate at a deposition rate of 1.1 Ångstroms per cycle to 2 Ångstroms per cycle, 1.1 Ångstroms per cycle to 1.9 Ångstroms per cycle, 1.1 Ångstroms per cycle to 1.8 Ångstroms per cycle, 1.1 Ångstroms per cycle to 1.7 Ångstroms per cycle, 1.1 Ångstroms per cycle to 1.6 Ångstroms per cycle, 1.1 Ångstroms per cycle to 1.5 Ångstroms per cycle, 1.1 Ångstroms per cycle to 1.4 Ångstroms per cycle, 1.1 Ångstroms per cycle to 1.3 Ångstroms per cycle, 1.1 Ångstroms per cycle to 1.2 Ångstroms per cycle, 1.2 Ångstroms per cycle to 1.9 Ångstroms per cycle, 1.3 Ångstroms per cycle to 1.9 Ångstroms per cycle, 1.4 Ångstroms per cycle to 1.9 Ångstroms per cycle, 1.5 Ångstroms per cycle to 1.9 Ångstroms per cycle, 1.6 Ångstroms per cycle to 1.9 Ångstroms per cycle, 1.7 Ångstroms per cycle to 1.9 Ångstroms per cycle, or 1.8 Ångstroms per cycle to 1.9 Ångstroms per cycle.

In some embodiments, when analyzed by Secondary Ion Mass Spectrometry (SIMS), the aluminum oxide film comprises less than 2% of halide atoms based on a total number of atoms in a cubic centimeter sample of the aluminum oxide film. For example, in some embodiments, the aluminum oxide film comprises 0.001% to 2% of halide atoms based on a total number of atoms in a cubic centimeter sample of the aluminum oxide film, or any range or subrange between 0.001% and 2%. In some embodiments, the aluminum oxide film comprises 0.001% to 2%, 0.001% to 1.9%, 0.001% to 1.8%, 0.001% to 1.7%, 0.001% to 1.6%, 0.001% to 1.5%, 0.001% to 1.4%, 0.001% to 1.3%, 0.001% to 1.2%, 0.001% to 1.1%, 0.001% to 1%, 0.001% to 0.9%, 0.001% to 0.8%, 0.001% to 0.7%, 0.001% to 0.6%, 0.001% to 0.5%, 0.001% to 0.4%, 0.001% to 0.3%, 0.001% to 0.2%, 0.001% to 0.1%, 0.001% to 0.01%, 0.01% to 2%, 0.1% to 2%, 0.2% to 2%, 0.3% to 2%, 0.4% to 2%, 0.5% to 2%, 0.6% to 2%, 0.7% to 2%, 0.8% to 2%, 0.9% to 2%, 1% to 2%, 1.1% to 2%, 1.2% to 2%, 1.3% to 2%, 1.4% to 2%, 1.5% to 2%, 1.6% to 2%, 1.7% to 2%, 1.8% to 2%, or 1.9% to 2% of halide atoms based on a total number of atoms in a cubic centimeter sample of the aluminum oxide film. In some embodiments, the halide atoms are bromide atoms and the film is substantially free of chloride atoms.

In some embodiments, a step coverage of the aluminum oxide film, on a feature having an aspect ratio of at least 2:1, is at least 90%. In some embodiments, the step coverage of the aluminum oxide film, on a feature having an aspect ratio of at least 2:1, is 90% to 99%, 90% to 98%, 90% to 97%, 90% to 96%, 90% to 95%, 90% to 94%, 90% to 93%, 90% to 92%, 90% to 91%, 91% to 99%, 92% to 99%, 93% to 99%, 94% to 99%, 95% to 99%, 96% to 99%, 97% to 99%, or 98% to 99%. In some embodiments, the step coverage of the aluminum oxide film, on a feature having an aspect ratio of at least 2:1, is 100%. The feature can have an aspect ratio of 2:1 to 100:1, 2:1 to 90:1, 2:1 to 80:1, 2:1 to 70:1, 2:1 to 60:1, 2:1 to 50:1, 2:1 to 40:1, 2:1 to 30:1, 2:1 to 20:1, 2:1 to 10:1, 2:1 to 9:1, 2:1 to 8:1, 2:1 to 7:1, 2:1 to 6:1, 2:1 to 5:1, 2:1 to 4:1, 2:1 to 3:1, 5:1 to 100:1, 10:1 to 100:1, 20:1 to 100:1, 30:1 to 100:1, 40:1 to 100:1, 50:1 to 100:1, 60:1 to 100:1, 70:1 to 100:1, 80:1 to 100:1, or 90:1 to 100:1. In some embodiments, the feature has an aspect ratio of greater than 100:1, such as, for example and without limitation, 1000:1, or any subrange between 100:1 and 1000:1.

The aspect ratio of the structure can refer to a ratio of two of a width, a depth, a height, a length, or a diameter, in any combination. In some embodiments, for example, the aspect ratio refers to the ratio of a depth of a circular hole (e.g., a pore, etc.) to a diameter of the circular hole (e.g., the pore, etc.). In some embodiments, the aspect ratio refers to the ratio of a depth of a non-circular hole (e.g., a trench, etc.) to a width of the non-circular hole (e.g., the trench, etc.). Non-limiting examples of substrates, including high-aspect ratio substrates, include, without limitation, at least one of a membrane, a showerhead, a liner, a tube, a gas line, a valve, an injector, a tray, or any combination thereof.

In some embodiments, when exposed to a substrate under deposition conditions, the aluminum bromide precursor and an oxidizer form the aluminum oxide film having a thickness that is within 10% of an average thickness of the aluminum oxide film. In some embodiments, the aluminum bromide precursor and an oxidizer form the aluminum oxide film having a thickness that is within 9%, 8%, 7%, 6%, 5%, 4%, 3%, 2%, 1%, or 0.1% of an average thickness of the aluminum oxide film.

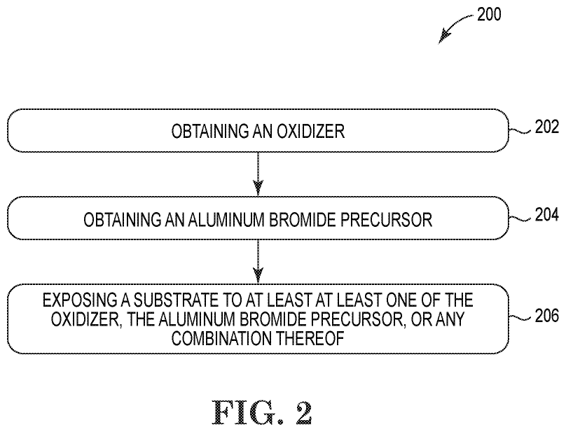

FIG. 2 is a flowchart of a method 200 for forming a film, according to some embodiments. As shown in FIG. 2, in some embodiments, the method 200 for forming a film comprises one or more of the following steps, in any order: obtaining 202 an oxidizer; obtaining 204 an aluminum bromide precursor; exposing 206, under deposition conditions, at least the substrate to at least one of the aluminum bromide precursor, the oxidizer, or any combination thereof, to form an aluminum oxide film on the substrate.

At step 202, the method 200 for forming a film comprises obtaining an oxidizer.

The oxidizer can comprise an oxidizing substance. For example, in some embodiments, the oxidizer comprises at least one of ozone (O₃), elemental oxygen (O), oxygen (O₂), water (H₂O), hydrogen peroxide (H₂O₂), nitrous oxide (N₂O), nitric oxide (NO), dinitrogen pentoxide (N₂O₅), nitrogen dioxide (NO₂), NO₃, or any combination thereof.

At step 204, the method 200 for forming a film comprises obtaining an aluminum bromide precursor.

The aluminum bromide precursor can comprise any one or more of the aluminum bromide precursors disclosed herein. For example, in some embodiments, the aluminum bromide precursor comprises AlBr₃ in a liquid phase. In some embodiments, the aluminum bromide precursor comprises AIBr₃ in a solid phase. In some embodiments, the aluminum bromide precursor comprises AlBr₃ in a gas/vapor phase. The aluminum bromide precursor can be obtained in a container or other vessel or other ampoule in which the aluminum bromide precursor is to be vaporized. It will further be appreciated that the step of obtaining can comprise obtaining any one or more of the assemblies and/or vessels disclosed herein, without departing from the scope of this disclosure. For example, in some embodiments, the obtaining comprises obtaining a vessel comprising the aluminum bromide precursor, optionally with or without trays.

Although not shown, in some embodiments, the method 200 comprises vaporizing the aluminum bromide precursor to obtain a vaporized aluminum bromide precursor.

The vaporizing may comprise heating the aluminum bromide precursor sufficient to obtain the vaporized aluminum bromide precursor. In some embodiments, the vaporizing comprises heating a container comprising the aluminum bromide precursor. In some embodiments, the vaporizing comprises heating the aluminum bromide precursor in a deposition chamber in which the deposition process is performed. In some embodiments, the vaporizing comprises heating a conduit for delivering the aluminum bromide precursor, the vaporized aluminum bromide precursor, or any combination thereof to, for example, a deposition chamber. In some embodiments, the vaporizing comprises operating a vapor delivery system comprising the aluminum bromide precursor. In some embodiments, the vaporizing comprises heating to a temperature sufficient to vaporize the aluminum bromide precursor to obtain the vaporized aluminum bromide precursor. In some embodiments, the vaporizing comprises heating to a temperature below a decomposition temperature of at least one of the aluminum bromide precursor, the vaporized aluminum bromide precursor, or any combination thereof. In some embodiments, the aluminum bromide precursor may be present in a gas phase or vapor phase, in which case this step is optional and not required. For example, in some embodiments, the aluminum bromide precursor comprises the vaporized aluminum bromide precursor.

Although not shown, in some embodiments, the method 200 comprises vaporizing the oxidizer to obtain a vaporized oxidizer.

The vaporizing may comprise heating the oxidizer sufficient to obtain the vaporized oxidizer. In some embodiments, the vaporizing comprises heating a container comprising the oxidizer. In some embodiments, the vaporizing comprises heating the oxidizer in a deposition chamber in which the deposition process is performed. In some embodiments, the vaporizing comprises heating a conduit for delivering the oxidizer, the vaporized oxidizer, or any combination thereof to, for example, a deposition chamber. In some embodiments, the vaporizing comprises operating a vapor delivery system comprising the oxidizer. In some embodiments, the vaporizing comprises heating to a temperature sufficient to vaporize the oxidizer to obtain the vaporized oxidizer. In some embodiments, the vaporizing comprises heating to a temperature below a decomposition temperature of at least one of the oxidizer, the vaporized oxidizer, or any combination thereof. In some embodiments, the oxidizer may be present in a gas phase or vapor phase, in which case this step is optional and not required. For example, in some embodiments, the oxidizer comprises the vaporized oxidizer.

At step 206, the method 200 for forming a film comprises exposing, under deposition conditions, at least a substrate to at least one of an oxidizer, an aluminum bromide precursor, or any combination thereof, to form an aluminum oxide film on the substrate.

The exposing may be performed in any system, apparatus, device, assembly, chamber thereof, or component thereof suitable for deposition processes, including, for example and without limitation, a deposition chamber, among others. In some embodiments, the exposing comprises contacting the substrate with at least one of the aluminum bromide precursor, the oxidizer, or any combination thereof. The aluminum bromide precursor and the oxidizer may be contacted with the substrate at the same time or at different times. For example, each of the aluminum bromide precursor, the oxidizer, and the substrate may be present in the deposition chamber at the same time. That is, in some embodiments, the contacting may comprise contemporaneous contacting or simultaneous contacting of the aluminum bromide precursor and the oxidizer with the substrate. Alternatively, each of the aluminum bromide precursor and the oxidizer may be present in the deposition chamber at different times. That is, in some embodiments, the contacting may comprise alternate and/or sequential contacting, in one or more cycles, of the aluminum bromide precursor and the oxidizer with the substrate and subsequently contacting the oxidizer with the substrate.

The deposition conditions may comprise conditions for deposition processes. Examples of deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The deposition conditions may comprise a deposition temperature. The deposition temperature may be a temperature less than the thermal decomposition temperature of at least one of the aluminum bromide precursor, the oxidizer, or any combination thereof. The deposition temperature may be sufficiently high to reduce or avoid condensation of at least one of the aluminum bromide precursor, the oxidizer, or any combination thereof. In some embodiments, the substrate may be heated to the deposition temperature. In some embodiments, the chamber or other vessel in which the substrate is contacted with the aluminum bromide precursor and the oxidizer is heated to the deposition temperature. In some embodiments, at least one of the aluminum bromide precursor, the oxidizer, or any combination thereof may be heated to the deposition temperature.

The deposition temperature may be a temperature of 200 °C to 2500 °C, or any range or subrange between 200 °C and 2500 °C. In some embodiments, the deposition temperature may be a temperature of 500 °C to 700 °C. For example, in some embodiments, the deposition temperature may be a temperature of 500 °C to 680 °C, 500 °C to 660 °C, 500 °C to 640 °C, 500 °C to 620 °C, 500 °C to 600 °C, 500 °C to 580 °C, 500 °C to 560 °C, 500 °C to 540 °C, 500 °C to 520 °C, 520 °C to 700 °C, 540 °C to 700 °C, 560 °C to 700 °C, 580 °C to 700 °C, 600 °C to 700 °C, 620 °C to 700 °C, 640 °C to 700 °C, 660 °C to 700 °C, or 680 °C to 700 °C. In other embodiments, the deposition temperature may be a temperature of greater than 200 °C to 2500 °C, such as, for example and without limitation, a temperature of 400 °C to 2000 °C, 550 °C to 2400 °C, 600 °C to 2400 °C, 625 °C to 2400 °C, 650 °C to 2400 °C, 675 °C to 2400 °C, 700 °C to 2400 °C, 725 °C to 2400 °C, 750 °C to 2400 °C, 775 °C to 2400 °C, 800 °C to 2400 °C, 825 °C to 2400 °C, 850 °C to 2400 °C, 875 °C to 2400 °C, 900 °C to 2400 °C, 925 °C to 2400 °C, 950 °C to 2400 °C, 975 °C to 2400 °C, 1000 °C to 2400 °C, 1025 °C to 2400 °C, 1050 °C to 2400 °C, 1075 °C to 2400 °C, 1100 °C to 2400 °C, 1200 °C to 2400 °C, 1300 °C to 2400 °C, 1400 °C to 2400 °C, 1500 °C to 2400 °C, 1600 °C to 2400 °C, 1700 °C to 2400 °C, 1800 °C to 2400 °C, 1900 °C to 2400 °C, 2000 °C to 2400 °C, 2100 °C to 2400 °C, 2200 °C to 2400 °C, 2300 °C to 2400 °C, 500 °C to 2000 °C, 500 °C to 1900 °C, 500 °C to 1800 °C, 500 °C to 1700 °C, 500 °C to 1600 °C, 500 °C to 1500 °C, 500 °C to 1400 °C, 500 °C to 1300 °C, 500 °C to 1200 °C, 500 °C to 1100 °C, 500 °C to 1000 °C, 500 °C to 900 °C, or 500 °C to 800 °C.

The vapor deposition conditions may comprise a deposition pressure. In some embodiments, the deposition pressure may comprise a vapor pressure of at least one of the aluminum bromide precursor, the oxidizer, or any combination thereof. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 m Torr to 100 m Torr, 1 mTorr to 90 m Torr, 1 m Torr to 80 m Torr, 1 m Torr to 70 m Torr, 1 m Torr to 60 m Torr, 1 m Torr to 50 mTorr, 1 mTorr to 40 m Torr, 1 mTorr to 30 m Torr, 1 m Torr to 20 m Torr, 1 m Torr to 10 mTorr, 100 m Torr to 300 m Torr, 150 m Torr to 300 m Torr, 200 m Torr to 300 m Torr, or 150 m Torr to 250 m Torr, or 150 mTorr to 225 m Torr.

In some embodiments, the exposing comprises pulsing the oxidizer into a chamber containing the substrate for a duration of 1 second to 10 minutes, or any range or subrange between 1 second and 10 minutes. For example, in some embodiments, the exposing comprises pulsing the oxidizer into a chamber containing the substrate for a duration of 1 second to 9 minutes, 1 second to 8 minutes, 1 second to 7 minutes, 1 second to 6 minutes, 1 second to 5 minutes, 1 second to 4 minutes, 1 second to 3 minutes, 1 second to 2 minutes, 1 second to 1 minute, 1 second to 50 seconds, 1 second to 40 seconds, 1 second to 30 seconds, 1 second to 20 seconds, 1 second to 10 seconds, 1 second to 5 seconds, 1 minute to 10 minutes, 2 minutes to 10 minutes, 3 minutes to 10 minutes, 4 minutes to 10 minutes, 5 minutes to 10 minutes, 6 minutes to 10 minutes, 7 minutes to 10 minutes, 8 minutes to 10 minutes, or 9 minutes to 10 minutes.

In some embodiments, exposing comprises pulsing the aluminum bromide precursor into a chamber containing the substrate for a duration of 1 second to 10 minutes, or any range or subrange between 1 second and 10 minutes. For example, in some embodiments, exposing comprises pulsing the aluminum bromide precursor into a chamber containing the substrate for a duration of 1 second to 9 minutes, 1 second to 8 minutes, 1 second to 7 minutes, 1 second to 6 minutes, 1 second to 5 minutes, 1 second to 4 minutes, 1 second to 3 minutes, 1 second to 2 minutes, 1 second to 1 minute, 1 second to 50 seconds, 1 second to 40 seconds, 1 second to 30 seconds, 1 second to 20 seconds, 1 second to 10 seconds, 1 second to 5 seconds, 1 minute to 10 minutes, 2 minutes to 10 minutes, 3 minutes to 10 minutes, 4 minutes to 10 minutes, 5 minutes to 10 minutes, 6 minutes to 10 minutes, 7 minutes to 10 minutes, 8 minutes to 10 minutes, or 9 minutes to 10 minutes.

In some embodiments, the aluminum bromide precursor achieves saturation at an oxidizer pulse duration of no greater than 10 seconds. For example, in some embodiments, the aluminum bromide precursor achieves saturation at an oxidizer pulse duration of no greater than 9 seconds, 8 seconds, 7 seconds, 6 seconds, 5 seconds, 4 seconds, 3 seconds, 2 seconds, or 1 second.

In some embodiments, exposing results in forming an aluminum oxide film at a deposition rate of at least 1.1 Angstroms per cycle. For example, in some embodiments, exposing results in forming an aluminum oxide film at a deposition rate of 1.1 Ångstroms per cycle to 2 Ångstroms per cycle, 1.1 Ångstroms per cycle to 1.9 Ångstroms per cycle, 1.1 Ångstroms per cycle to 1.8 Ångstroms per cycle, 1.1 Ångstroms per cycle to 1.7 Ångstroms per cycle, 1.1 Ångstroms per cycle to 1.6 Ångstroms per cycle, 1.1 Ångstroms per cycle to 1.5 Ångstroms per cycle, 1.1 Ångstroms per cycle to 1.4 Ångstroms per cycle, 1.1 Ångstroms per cycle to 1.3 Ångstroms per cycle, 1.1 Ångstroms per cycle to 1.2 Ångstroms per cycle, 1.2 Ångstroms per cycle to 1.9 Ångstroms per cycle, 1.3 Ångstroms per cycle to 1.9 Ångstroms per cycle, 1.4 Ångstroms per cycle to 1.9 Ångstroms per cycle, 1.5 Ångstroms per cycle to 1.9 Ångstroms per cycle, 1.6 Ångstroms per cycle to 1.9 Ångstroms per cycle, 1.7 Ångstroms per cycle to 1.9 Ångstroms per cycle, or 1.8 Ångstroms per cycle to 1.9 Ångstroms per cycle.

In some embodiments, exposing results in forming an aluminum oxide film having a thickness that is within 10% of an average thickness of the aluminum oxide film. For example, in some embodiments, exposing results in forming an aluminum oxide film having a thickness that is within 9%, 8%, 7%, 6%, 5%, 4%, 3%, 2%, 1%, or 0.1% of an average thickness of the aluminum oxide film.

The substrate may comprise at least one of Si, Co, Cu, Al, W, WN, WC, TIN, Mo, MOC, SiO₂, SiN, WCN, Al₂O₃, AlN, ZrO₂, La₂O₃, TaN, RuO₂, IrO₂, Nb₂O₃, Y₂O₃, hafnium oxide, or any combination thereof. Any substrate suitable for aluminum trichloride deposition may be reasonably used with aluminum tribromide deposition.

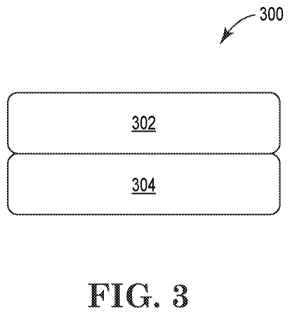

FIG. 3 is a schematic diagram of a cross-section of a component 300, according to some embodiments. As shown in FIG. 3, in some embodiments, the component 300 comprises an aluminum oxide film 302 on a substrate 304. It will be appreciated that the aluminum oxide film can be formed on the substrate 304 according to any one or more of the methods disclosed herein and/or formed from any one or more of the aluminum bromide precursors and/or oxidizers disclosed herein, without departing from the scope of this disclosure. It will further be appreciated that the substrate can comprise any one or more of the substrates disclosed herein, without departing from the scope of this disclosure.

In some embodiments, when analyzed by Secondary Ion Mass Spectrometry (SIMS), the aluminum oxide film comprises less than 2% of halide atoms based on a total number of atoms in a cubic centimeter sample of the aluminum oxide film. In some embodiments, when analyzed by Secondary Ion Mass Spectrometry (SIMS), the aluminum oxide film comprises less than 0.5% of halide atoms based on a total number of atoms in a cubic centimeter sample of the aluminum oxide film. In some embodiments, the halide atoms are bromide atoms and the film is substantially free of chloride atoms.

In some embodiments, a step coverage of the aluminum oxide film, on a feature having an aspect ratio of at least 2:1, is at least 90%. In some embodiments, the step coverage of the aluminum oxide film, on a feature having an aspect ratio of at least 2:1, is 90% to 99%, 90% to 98%, 90% to 97%, 90% to 96%, 90% to 95%, 90% to 94%, 90% to 93%, 90% to 92%, 90% to 91%, 91% to 99%, 92% to 99%, 93% to 99%, 94% to 99%, 95% to 99%, 96% to 99%, 97% to 99%, or 98% to 99%. In some embodiments, the step coverage of the aluminum oxide film, on a feature having an aspect ratio of at least 2:1, is 100%. The feature can have an aspect ratio of 2:1 to 100:1, 2:1 to 90:1, 2:1 to 80:1, 2:1 to 70:1, 2:1 to 60:1, 2:1 to 50:1, 2:1 to 40:1, 2:1 to 30:1, 2:1 to 20:1, 2:1 to 10:1, 2:1 to 9:1, 2:1 to 8:1, 2:1 to 7:1, 2:1 to 6:1, 2:1 to 5:1, 2:1 to 4:1, 2:1 to 3:1, 5:1 to 100:1, 10:1 to 100:1, 20:1 to 100:1, 30:1 to 100:1, 40:1 to 100:1, 50:1 to 100:1, 60:1 to 100:1, 70:1 to 100:1, 80:1 to 100:1, or 90:1 to 100:1. In some embodiments, the feature has an aspect ratio of greater than 100:1, such as, for example and without limitation, 1000:1, or any subrange between 100:1 and 1000:1.

In some embodiments, a thickness of the aluminum oxide film is within 10% of an average thickness of the aluminum oxide film. In some embodiments, a thickness of the aluminum oxide film is within 9%, 8%, 7%, 6%, 5%, 4%, 3%, 2%, 1%, or 0.1% of an average thickness of the aluminum oxide film.

Any one or more of the embodiments disclosed herein shall be understood to be combinable without departing from the scope or spirit of the disclosure.

### Example 1

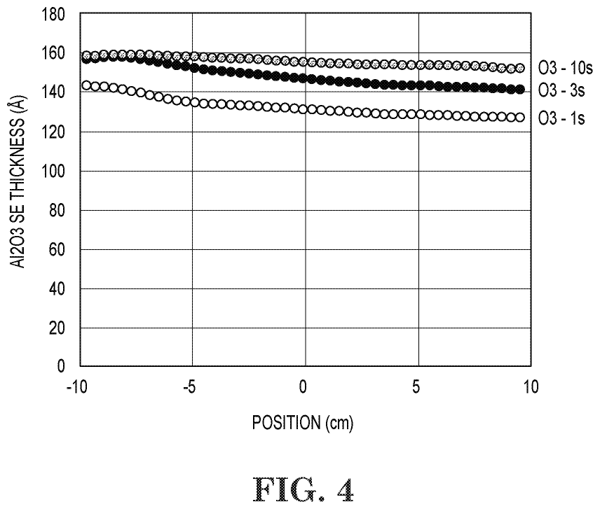

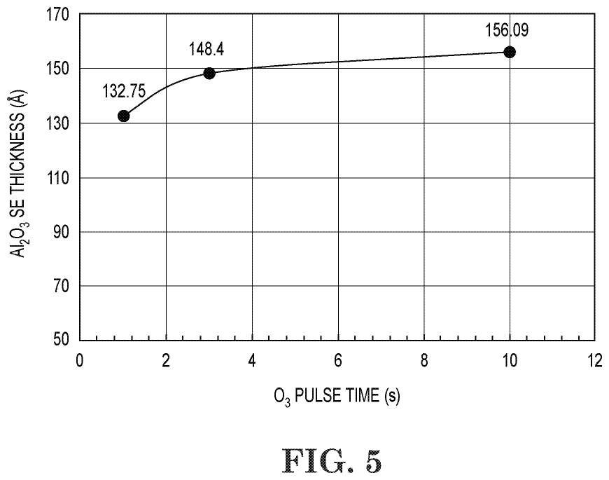

An AlBr₃ precursor was deposited by atomic layer deposition (ALD), with ozone (O₃) used as co-reactant, to form Al₂O₃ films. The conditions for the ALD process are summarized in the table below. The film thickness at different locations of the substrate, as well as the film thickness for varying ozone pulse times were evaluated, and are summarized in FIGS. 4 and 5, respectively.

| ALD Conditions | Values |
|---|---|
| # of ALD Cycles | 100 |
| Reactor Temperature | 250 °C |
| AlBr₃ Ampoule Temperature | 80 °C |
| AlBr₃ Pulse Duration | 1 s |
| AlBr₃ Purge Duration | 5 s |
| O₃ Pulse Duration | 1 s to 10 s |
| O₃ Purge Duration | 5 s to 10 s |

A saturation ratio was calculated by taking the ratio of the film thickness for a 10 second ozone pulse time to the film thickness for a 3 second ozone pulse time. Based on the data presented in FIG. 5, the saturation ratio was calculated to be approximately 1.06 (156.09/148.4). With a saturation ratio of less than 1.1, efficient and stable ALD growth was confirmed, without requiring significant excess ozone usage, thus minimizing reactant waste, while maintaining film quality. In addition, ozone saturation was achieved with a 3 second pulse time.

### Example 2

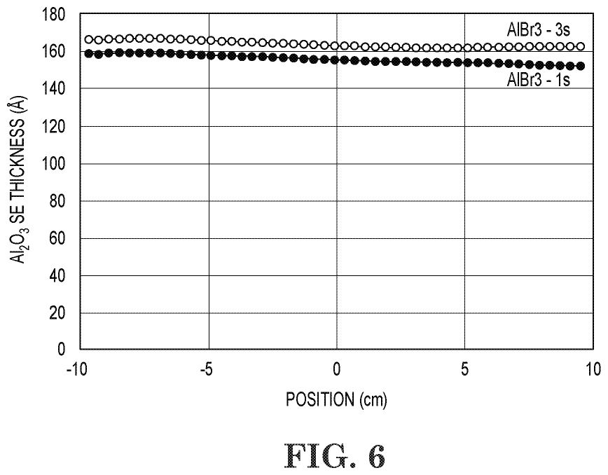

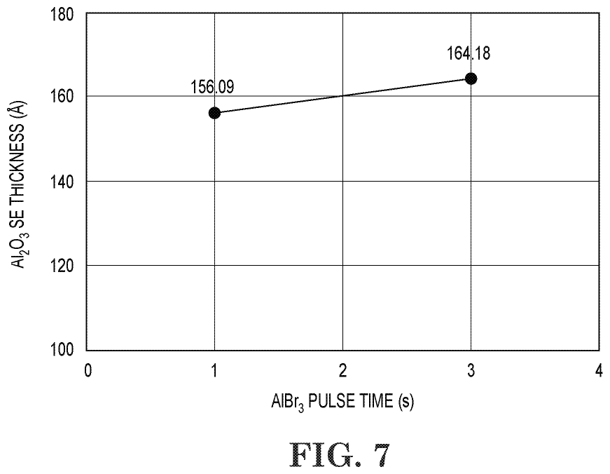

An AlBr₃ precursor was deposited by atomic layer deposition (ALD), with ozone (O₃) used as co-reactant, to form Al₂O₃ films. The conditions for the ALD process are summarized in the table below. The film thickness at different locations of the substrate, as well as the film thickness for varying precursor pulse times were evaluated, and are summarized in FIGS. 6 and 7, respectively.

| ALD Conditions | Values |
|---|---|
| # of ALD Cycles | 100 |
| Reactor Temperature | 250 °C |
| AlBr₃ Ampoule Temperature | 80 °C |
| AlBr₃ Pulse Duration | 1 s to 3 s |
| AlBr₃ Purge Duration | 5 s |
| O₃ Pulse Duration | 10 s |
| O₃ Purge Duration | 30 s |

A saturation ratio was calculated by taking the ratio of the film thickness for a 3 second precursor pulse time to the film thickness for a 1 second precursor pulse time. Based on the data presented in FIG. 7, the saturation ratio was calculated to be approximately 1.05 (164.18/156.09). With a saturation ratio of less than 1.1, efficient and stable ALD growth was confirmed, without requiring significant excess precursor usage, thus minimizing precursor waste, while maintaining film quality. In addition, precursor saturation was achieved with a 1 second pulse time.

### Example 3

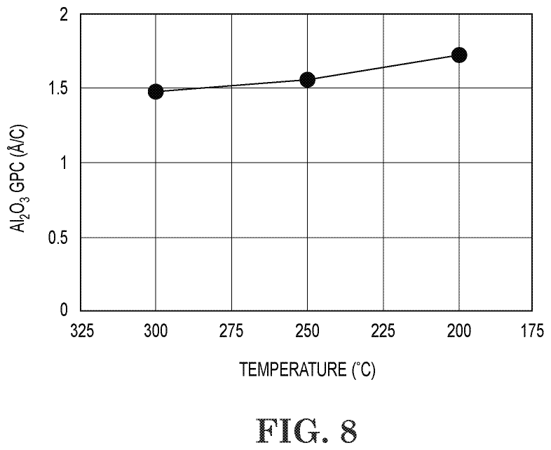

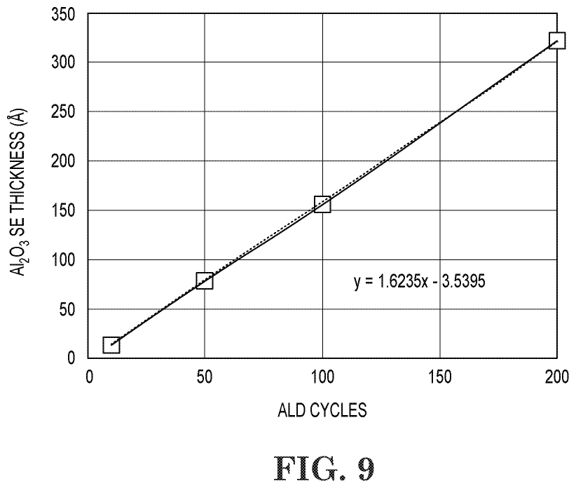

An AlBr₃ precursor was deposited by atomic layer deposition (ALD), with ozone (O₃) used as co-reactant, to form Al₂O₃ films. The conditions for the ALD process are summarized in the table below. The deposition rate of the precursor for various temperatures, as well as the film thickness for varying number of cycles were evaluated, and are summarized in FIGS. 8 and 9, respectively.

| ALD Conditions | Values |
|---|---|
| # of ALD Cycles | 10-200 |
| Reactor Temperature | 200 °C to 300 °C |
| AlBr₃ Ampoule Temperature | 80 °C |
| AlBr₃ Pulse Duration | 1 s |
| AlBr₃ Purge Duration | 5 s |
| O₃ Pulse Duration | 10 s |
| O₃ Purge Duration | 30 s |

As shown in FIG. 8, the precursor exhibited stable ALD growth across the entire temperature range of 200 °C to 300 °C, with ozone used as the co-reactant. As shown in FIG. 9, film thickness at 250 °C was linear for varying number of cycles, demonstrating process reliability and uniformity. Fitting the data in FIG. 9 to a linear regression revealed that the precursor also exhibited a growth rate of 1.6 Angstroms/cycle.

### Example 4

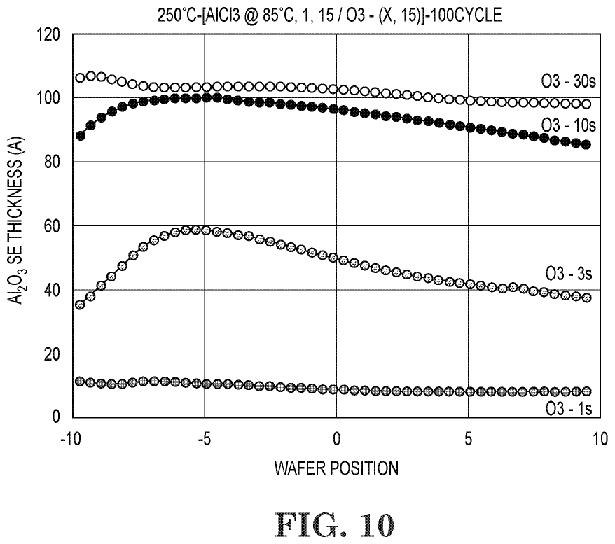

Various precursors were deposited by atomic layer deposition, with ozone used as the co-reactant, to form Al₂O₃ films. The ozone saturation curves and deposition rate for various Al precursors were evaluated and are summarized in the table below and FIG. 10.

| | AIBr3 | AICI3 | TMA* |
|---|---|---|---|
| | Precursor | Precursor | Precursor |
| Ozone Saturation | 3 s | 10 s | 1 s |
| Deposition Rate | 1.6 | 0.95 | 0.95 |
| (Angstroms/cycle) | | | |

*TMA = trimethylaluminum

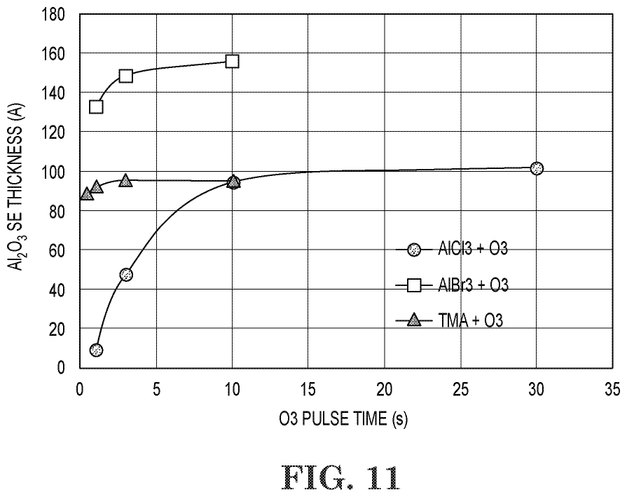

As shown in FIG. 10, AlBr₃ precursor exhibited superior ozone reactivity relative to the other precursors in ALD processes, as demonstrated by achieving saturation more efficiently with shorter ozone pulse times and by providing higher deposition rates than the other precursors. In contrast, AlCl₃, for example, required longer ozone pulse times to achieve saturation and exhibited lower deposition efficiency. FIG. 11 shows the impact of ozone pulse time on Al₂O₃ film thickness accumulation for AlCl₃, AIBr₃, and trimethylaluminum.

### Example 5

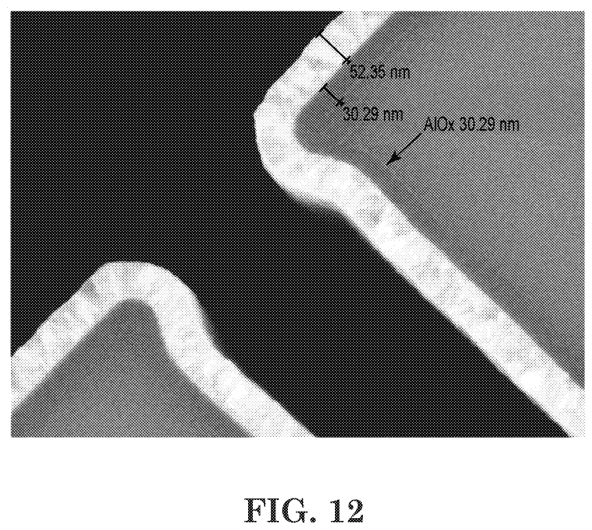

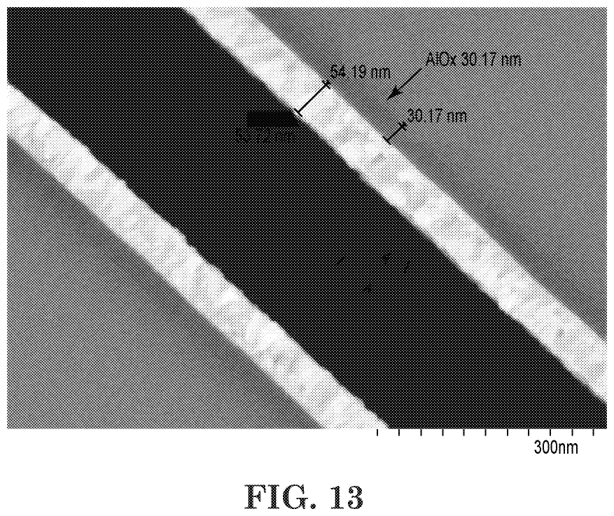

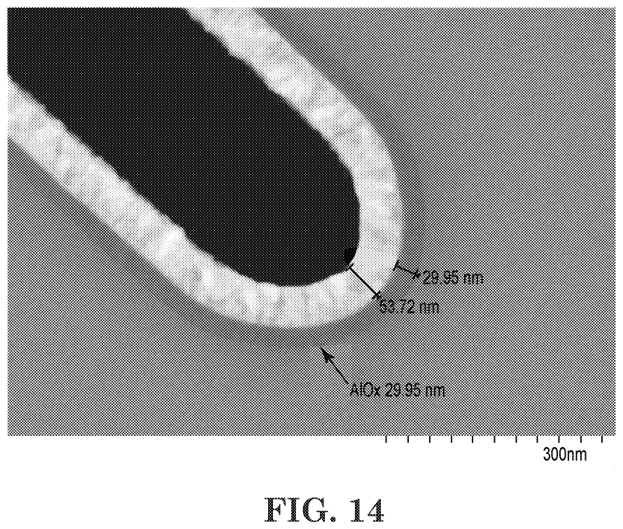

An AlBr₃ precursor was deposited by atomic layer deposition (ALD), with ozone (O₃) used as co-reactant, to form an Al₂O₃ film on a trench having an aspect ratio of 9:1. Scanning electron microscopy (SEM) was used to evaluate and calculate the step coverage (54 nm ZrO₂ was deposited for enhancing the image). To calculate the step coverage of the resulting film, the ratio of the film thickness at the bottom of the trench to the film thickness on the top surface was calculated. Based on the thickness provided in FIGS. 12-14, the step coverage was calculated to be approximately 99%.

### Example 6

Various precursors were deposited by atomic layer deposition, with ozone used as the co-reactant, to form Al₂O₃ films. The impurities present in films formed using each of the precursors was evaluated using Secondary Ion Mass Spectrometry (SIMS). The results are summarized in the table below.

| ALD | Deposition Rate | | | | |
|---|---|---|---|---|---|
| Process | (Angstroms/cycle) | C | H | CI | Br |
| AlBr₃ + O₃ | 1.6 | 0.007% | 0.085% | n/a | 0.128% |
| AlCl₃ + O₃ | 0.95 | 0.008% | 0.171% | 2% | n/a |
| TMA + O₃ | 0.95 | 0.342% | 0.342% | n/a | n/a |

As shown in the table above, use of AlBr₃ precursor with ozone as co-reactant produced films with the lower levels of C and H contamination. For example, although use of AlBr₃ precursor with ozone as co-reactant also produced films with 0.128% Br, use of TMA precursor with ozone resulted in higher levels of C and H impurities. In addition, AlCl₃ precursor with ozone had the highest levels of halide impurities relative to AlBr₃ precursor and TMA precursor. For example, use of AlBr₃ precursor and ozone resulted in 16 times less halide impurity levels as compared to use of AlCl₃ precursor and ozone.

### Aspects

Various Aspects are described below. It is to be understood that any one or more of the features recited in the following Aspect(s) can be combined with any one or more other Aspect(s).
Aspect 1. An assembly comprising:
   a vessel; and
   an aluminum bromide precursor located within an interior volume of the vessel,
   wherein the vessel is configured to store and supply the aluminum bromide precursor to a film deposition process; and
   wherein, when exposed to a substrate under deposition conditions, the aluminum bromide precursor and an oxidizer form an aluminum oxide film.
Aspect 2. The assembly according to Aspect 1, wherein the aluminum bromide precursor is contained in the interior volume of the vessel under conditions where the aluminum bromide precursor is present as a liquid.
Aspect 3. The assembly according to any one of Aspects 1-2, wherein the aluminum bromide precursor is contained in the interior volume of the vessel under conditions where the aluminum bromide precursor is present as a solid.
Aspect 4. The assembly according to any one of Aspects 1-3, further comprising: at least one tray,
   wherein the at least one tray is located within the interior volume of the vessel; and
   wherein the aluminum bromide precursor is located on the at least one tray.
Aspect 5. The assembly according to Aspect 4, wherein the at least one tray comprises a graphite material.
Aspect 6. The assembly according to Aspect 4 or 5, wherein the at least one tray comprises at least one of an aluminum material, an alloy material, or any combination thereof.
Aspect 7. The assembly according to any one of Aspects 1-6, wherein, when exposed under deposition conditions to a substrate, the aluminum bromide precursor and an oxidizer form a film on a substrate at a deposition rate of at least 1.1 Ångstroms per cycle.
Aspect 8. The assembly according to any one of Aspects 1-7, wherein, when analyzed by Secondary Ion Mass Spectrometry (SIMS), the aluminum oxide film comprises less than 2% of bromide atoms and is substantially free of chloride atoms based on a total number of atoms in a cubic centimeter sample of the aluminum oxide film.
Aspect 9. The assembly according to any one of Aspects 1-8, wherein a step coverage of the aluminum oxide film, on a feature having an aspect ratio of at least 2:1, is at least 90%.
Aspect 10. The assembly according to any one of Aspects 1-9, wherein, when exposed to a substrate under deposition conditions, the aluminum bromide precursor and an oxidizer form the aluminum oxide film having a thickness that is within 10% of an average thickness of the aluminum oxide film.
Aspect 11. A method comprising:
   obtaining an oxidizer;
   obtaining an aluminum bromide precursor;
   exposing, under deposition conditions, a substrate to at least an oxidizer; and
   exposing, under deposition conditions, the substrate to at least the aluminum bromide precursor to form an aluminum oxide film on the substrate.
Aspect 12. The method according to Aspect 11, wherein exposing comprises pulsing the oxidizer into a chamber containing the substrate for a duration of 1 second to 10 minutes.
Aspect 13. The method according to any one of Aspects 11-12, wherein exposing comprises pulsing the aluminum bromide precursor into a chamber containing the substrate for a duration of 1 second to 1 minute.
Aspect 14. The method according to any one of Aspects 11-13, wherein the aluminum bromide precursor achieves saturation at an oxidizer pulse duration of no greater than 60 seconds.
Aspect 15. The method according to any one of Aspects 11-14, wherein exposing results in forming an aluminum oxide film at a deposition rate of at least 1.1 Angstroms per cycle.
Aspect 16. The method according to any one of Aspects 11-15, wherein exposing results in forming an aluminum oxide film having a thickness that is within 10% of an average thickness of the aluminum oxide film.
Aspect 17. A component comprising:
   a substrate; and
   an aluminum oxide film located on the substrate,
   wherein, when analyzed by Secondary Ion Mass Spectrometry (SIMS), the aluminum oxide film comprises more than 0% and less than 2% of bromide atoms and substantially free of chloride atoms based on a total number of atoms in a cubic centimeter sample of the aluminum oxide film.
Aspect 18. The component according to Aspect 17, wherein a step coverage of the aluminum oxide film, on a feature having an aspect ratio of at least 2:1, is at least 90%.
Aspect 19. The component according to any one of Aspects 17-18, wherein, when analyzed by Secondary Ion Mass Spectrometry (SIMS), the aluminum oxide film comprises less than 0.5% of bromide atoms based on a total number of atoms in a cubic centimeter sample of the aluminum oxide film.
Aspect 20. The component according to any one of Aspects 17-19, wherein a thickness of the aluminum oxide film is within 10% of an average thickness of the aluminum oxide film.

What is claimed is:

1. An assembly comprising:
a vessel; and
an aluminum bromide precursor located within an interior volume of the vessel,
wherein the vessel is configured to store and supply the aluminum bromide precursor to a film deposition process; and
wherein, when exposed to a substrate under deposition conditions, the aluminum bromide precursor and an oxidizer form an aluminum oxide film.

2. The assembly of claim 1, wherein the aluminum bromide precursor is contained in the interior volume of the vessel under conditions where the aluminum bromide precursor is present as a liquid.

3. The assembly of claim 1, wherein the aluminum bromide precursor is contained in the interior volume of the vessel under conditions where the aluminum bromide precursor is present as a solid.

4. The assembly of claim 1, further comprising:
at least one tray,
wherein the at least one tray is located within the interior volume of the vessel; and
wherein the aluminum bromide precursor is located on the at least one tray.

5. The assembly of claim 4, wherein the at least one tray comprises a graphite material.

6. The assembly of claim 4, wherein the at least one tray comprises at least one of an aluminum material, an alloy material, or any combination thereof.

7. The assembly of claim 1, wherein, when exposed under deposition conditions to a substrate, the aluminum bromide precursor and an oxidizer form a film on a substrate at a deposition rate of at least 1.1 Ångstroms per cycle.

8. The assembly of claim 1, wherein, when analyzed by Secondary Ion Mass Spectrometry (SIMS), the aluminum oxide film comprises less than 2% of bromide atoms and is substantially free of chloride atoms based on a total number of atoms in a cubic centimeter sample of the aluminum oxide film.

9. The assembly of claim 1, wherein a step coverage of the aluminum oxide film, on a feature having an aspect ratio of at least 2:1, is at least 90%.

10. The assembly of claim 1, wherein, when exposed to a substrate under deposition conditions, the aluminum bromide precursor and an oxidizer form the aluminum oxide film having a thickness that is within 10% of an average thickness of the aluminum oxide film.

11. A method comprising:
obtaining an oxidizer;
obtaining an aluminum bromide precursor;
exposing, under deposition conditions, a substrate to at least an oxidizer; and
exposing, under deposition conditions, the substrate to at least the aluminum bromide precursor to form an aluminum oxide film on the substrate.

12. The method of claim 11, wherein exposing comprises pulsing the oxidizer into a chamber containing the substrate for a duration of 1 second to 10 minutes.

13. The method of claim 11, wherein exposing comprises pulsing the aluminum bromide precursor into a chamber containing the substrate for a duration of 1 second to 1 minute.

14. The method of claim 11, wherein the aluminum bromide precursor achieves saturation at an oxidizer pulse duration of no greater than 60 seconds.

15. The method of claim 11, wherein exposing results in forming an aluminum oxide film at a deposition rate of at least 1.1 Ångstroms per cycle.

16. The method of claim 11, wherein exposing results in forming an aluminum oxide film having a thickness that is within 10% of an average thickness of the aluminum oxide film.

17. A component comprising:
a substrate; and
an aluminum oxide film located on the substrate,
wherein, when analyzed by Secondary Ion Mass Spectrometry (SIMS), the aluminum oxide film comprises more than 0% and less than 2% of bromide atoms and substantially free of chloride atoms based on a total number of atoms in a cubic centimeter sample of the aluminum oxide film.

18. The component of claim 17, wherein a step coverage of the aluminum oxide film, on a feature having an aspect ratio of at least 2:1, is at least 90%.

19. The component of claim 17, wherein, when analyzed by Secondary Ion Mass Spectrometry (SIMS), the aluminum oxide film comprises less than 0.5% of bromide atoms based on a total number of atoms in a cubic centimeter sample of the aluminum oxide film.

20. The component of claim 17, wherein a thickness of the aluminum oxide film is within 10% of an average thickness of the aluminum oxide film.
